(19) United States
(12) Patent Application Publication
(10) Pub. No.: US 2005/0275085 A1
(43) Pub. Date: Dec. 15, 2005

(54) Arrangement for reducing the electrical crosstalk on a chip

(76) Inventors: Axel Brintzinger, Dresden (DE); Octavio Trovarelli, Dresden (DE); Ingo Uhlendorf, (US); Stefan Ruckmich, Dresden (DE); David Wallis, Dresden (DE); Fritz Uhlendorf, Stade (DE); Helga Uhlendorf, Stade (DE)

Correspondence Address: SLATER & MATSIL LLP, 17950 PRESTON ROAD, SUITE 1000, DALLAS, TX, 75252, US

(21) Appl. No.: 11/140,578

(22) Filed: May 27, 2005

(30) Foreign Application Priority Data
May 27, 2004 (DE) 10 2004 026 549.6
Jul. 20, 2004 (DE) 10 2004 035 080.9

(51) Int. Cl. H01L 23/12

(52) U.S. Cl. 257/700; 257/758

(57) ABSTRACT

An arrangement reduces the electrical crosstalk on a chip, in particular between adjacent conductors of the redistribution routing and/or between the redistribution routing on the first passivation on the chip and the metallization of the chip. In one aspect, the arrangement reduces the crosstalk between the redistribution wiring on a chip and its metallization and can be realized simply and independently at the front end. This is achieved by at least an additional conductor (10) being respectively arranged between adjacent conductors of the redistribution routing (1) and/or at least a second passivation (7) with a lower dielectric constant of a preferred “cold dielectric” being arranged between the redistribution routing (1) and the first passivation (2) on the active region of the chip (3).

This application claims priority to German Patent Application 10 2004 026 549.6, which has filed May 27, 2004, and to German Patent Application 10 2004 035 080.9, which was filed Jul. 20, 2004, both of which are incorporated herein by reference.

### TECHNICAL FIELD

The invention relates to an arrangement for reducing the electrical crosstalk on a chip, in particular between adjacent conductors of the redistribution routing and/or between the redistribution routing on the first passivation on the chip and the metallization of the chip.

### BACKGROUND

One of the fundamental problems concerning the electrical performance of semiconductor components with redistribution routing on the active side of the chip is how to avoid the electrical crosstalk (capacitive, inductive) between adjacent conductors of the redistribution routing or between the redistribution routing and the active region of the chip or its metallization under the redistribution routing. This is particularly critical at high clock frequencies, which can lead to the function of the chip no longer being ensured.

The redistribution routing on the active side of a chip is used for “rerouting” the bonding pads necessary for the electrical contacting to the outside. For example bond pads disposed in a central arrangement of one or more rows on the chip can be rerouted into a more favorable arrangement, for example an array of contact bumps (e.g., compliant elements), or in a distributed manner to the edge of the chip.

An example of such redistribution routing is disclosed in U.S. Pat. No. 6,389,691 B1, which is incorporated herein by reference. Here, a method of forming redistribution routing with associated solder bumps is described. The redistribution routing is built up on the uppermost passivation of the chip, with only the bonding pads being kept free, so that an electrical contact of the redistribution routing with the bonding pad is possible.

Usually, the redistribution routing is produced as a stack comprising a Cu layer, an Ni layer and a top layer of Au, and is deposited on the first (uppermost) passivation of the chip. Before the layers mentioned are deposited, firstly a resist is deposited on the passivation and photolithographically patterned. After the deposition of the redistribution routing, the resist is then removed, for example by stripping. The redistribution routing usually comprises conductors made to extend more or less in parallel over wide ranges, which, because of the miniaturized construction, are all in close inductive and/or capacitive proximity to one another.

In the simulation of the electrical functionality of such arrangements it has been found that reliable functioning is no longer ensured, in particular in the case of applications with high clock frequencies, because of the inductive and/or capacitive crosstalk.

In principle, there is the possibility here of increasing the thickness of the passivation layer, which is restricted however by the fact that the thickness of the passivation must not exceed 5 μm in order to allow fuses still to open after the passivation has been deposited.

### SUMMARY OF THE INVENTION

Embodiments of the invention provide an arrangement for reducing the electrical crosstalk between adjacent conductors of the redistribution wiring or between the redistribution wiring on a chip and its metallization that can be realized simply and independently at the front end and with which a distinct reduction of the crosstalk can be achieved.

In one example, the invention provides an arrangement that includes at least a shielding that is respectively arranged between adjacent conductors of the redistribution routing. In another example, at least a second passivation with a lower dielectric constant of a preferred cold dielectric is arranged between the redistribution routing and the first passivation on the active region of the chip. These two examples can be combined.

The shielding extending between two adjacent conductors of the redistribution routing is preferably formed as an additional conductor. Although the crosstalk takes place between the conductor of the redistribution routing and the additional conductor, no further crosstalk from one of the conductors of the redistribution routing to the adjacent conductors of the redistribution routing takes place because of the lower field strength.

The second passivation achieves the effect of electrically isolating the redistribution routing by increasing the distance between the redistribution routing and the active regions of the chip, whereby the electrical performance is distinctly improved, in particular at high clock frequencies, accompanied by better signal transmission. The invention may be used in the case of any Wafer Level Packages (WLP) and also for stacked packages. In particular, the invention reduces the crosstalk between the redistribution routing (RDL) and the M2 metallization on the chip.

In a first configuration of the invention, the second passivation extends with a small layer thickness over the entire surface of the first passivation. In this case, the layer thickness of the passivation can be adapted without any problem to the respective requirements.

In a second configuration of the invention, the second passivation is arranged only under the region of the redistribution routing. The particular advantage of this configuration is that the thickness of the second passivation can be chosen completely freely, that is to say that optimum isolation can be achieved by increasing the distance between the redistribution routing and the metallization, without causing problems with the exposure of fuses. Here, too, crosstalk between the redistribution routing (RDL) and the M2 metallization on the chip is reduced, and in addition also the crosstalk from redistribution routing to redistribution routing, because here there is an air gap between the redistribution routings, which has a lower dielectric constant than any other dielectric.

The second passivation preferably comprises a dielectric photo-patternable material, such as a photoresist.

It is expedient that the additional conductor extending between adjacent conductors of the redistribution routing is connected to ground, since the information transferred by crosstalk to the additional conductor is consequently diverted to ground.

For better diversion of the crosstalk on the additional conductor and consequently for better shielding of the adjacent conductor of the redistribution routing, it is advantageous that the additional conductor extends substantially in parallel between adjacent conductors of the redistribution routing. In this case, the additional conductors may be arranged with preference in the layer level of the redistribution routing.

In addition, it may be provided that a dielectric, preferably air, is arranged between the conductor of the redistribution routing and the additional conductor. In this way, the mutual shielding between two adjacent conductors of the redistribution routing is improved in the sense described above.

Alternatively or additionally, a conductor of the redistribution routing may be arranged between two additional conductors.

### BRIEF DESCRIPTION OF THE DRAWINGS

The invention is explained in more detail below by exemplary embodiments. In the associated drawings:

FIG. 1 shows a schematic representation of a redistribution routing on a first passivation over an active region of a chip (prior art);

FIG. 2 shows a schematic sectional representation of a redistribution routing on a second passivation deposited over the entire surface area;

FIG. 3 shows a schematic representation of a second passivation, which is formed only under the redistribution routing;

FIG. 4 shows a schematic representation of the redistribution routing corresponding to FIG. 3 with an “air gap” between the individual traces of the redistribution routing;

FIG. 5 shows a plan view of a schematic representation of a detail of the redistribution routing in one layer level (prior art); and

FIG. 6 shows the plan view of a schematic representation of a detail in the redistribution routing level with shielding by conductors connected to ground.

The following list of reference symbols can be used in conjunction with the figures:
1 redistribution routing
2 first passivation
3 chip
4 Cu layer
5 Ni layer
6 Au layer
7 second passivation
8 “air gap”
9 distance
10 conductor connected to ground
11 dielectric

### DETAILED DESCRIPTION OF ILLUSTRATIVE EMBODIMENTS

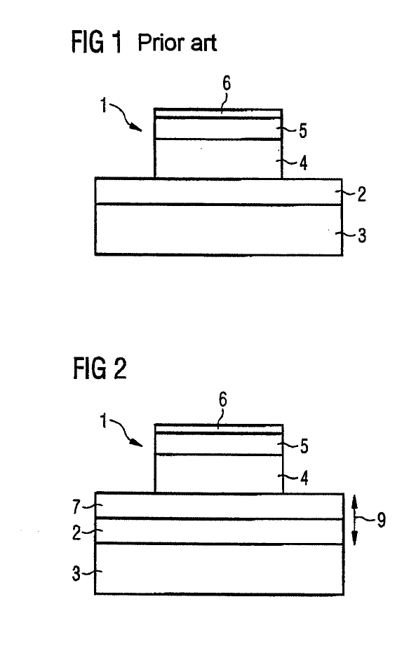

FIG. 1 shows a schematic sectional representation of a typical redistribution routing 1 (redistribution layer) on a first passivation 2 on the active side of a chip 3 corresponding to the prior art. With such redistribution routing 1, the bonding pads on a chip are usually “relocated” to more favorable positions, for example from a central row of bonding pads to an array of contacts on the active chip side.

The photolithographically patterned redistribution routing 1 on the first passivation 2 comprises a sequence of layers of a Cu layer 4 at the bottom, an Ni layer 5 applied over that and an Au layer 6, which ensures the solderability of the redistribution routing 1.

FIG. 2 reveals a schematic sectional representation of a redistribution routing 1 on a second passivation 7, deposited over the full surface area over the first passivation 2 in a way according to an embodiment for increasing the distance 9 between the redistribution routing 1 and the metallization of the chip 3. The second passivation 7, for example a polyimide or a cold dielectric, should have a distinctly lower dielectric constant than the first passivation layer 2, so that a distinctly better electrical isolation of the redistribution routing from the upper metallization (e.g., M2 for double metal device) of the chip 3 is achieved with approximately the same or an only slightly greater overall layer thickness than the first passivation 2 from FIG. 1.

This second dielectric 7 may preferably comprise a photosensitive material, the curing temperature of which is low enough to avoid deterioration of the chip performance as a result of the prescribed thermal budget (“cold dielectric”). In other words, a cold dielectric should be a material that can be deposited at a low temperature, e.g., a temperature below that at which the first passivation 2 is deposited.

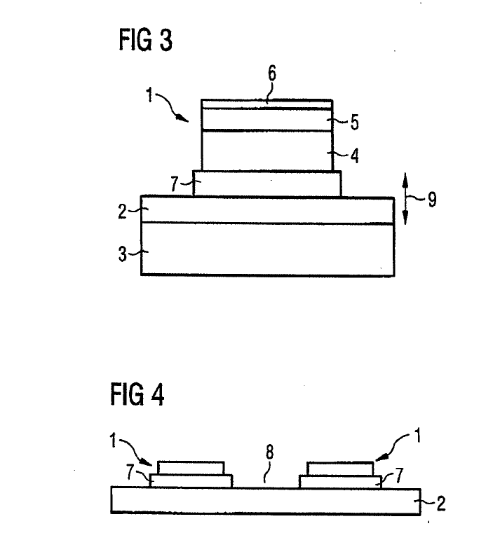

FIG. 3 reveals a special configuration of the invention in which particularly good isolation of the redistribution routing 1 with respect to the metallization of the chip 3 is achieved.

FIG. 3 shows a schematic sectional representation with a second passivation 7, which is formed only under the redistribution routing 1, that is to say is patterned. The second passivation 7 may also protrude laterally under the redistribution routing 1. The particular advantage here is that a lower dielectric constant is realized under the redistribution routing 1, or the distance 9 between the redistribution routing 1 and the metallization of the chip 3 can be distinctly increased without having to accept disadvantages in return. The crosstalk is thereby reduced to a negligible level or prevented entirely, so that particularly high clock frequencies are also possible. The first passivation 2 can be kept as thin as possible here, in accordance with the technological requirements, so that fuses can easily be opened. The second passivation 7 (the cold dielectric) can then be formed significantly thicker.

FIG. 4 shows a schematic representation of the redistribution routing 1 corresponding to FIG. 3 with an “air gap” 8 between the individual traces of the redistribution routing 1 and a second passivation 7 under the redistribution routing. The low dielectric constant of the “air gap” has the effect of also reducing, or preventing, the horizontal crosstalk between individual traces of the redistribution routing 1.

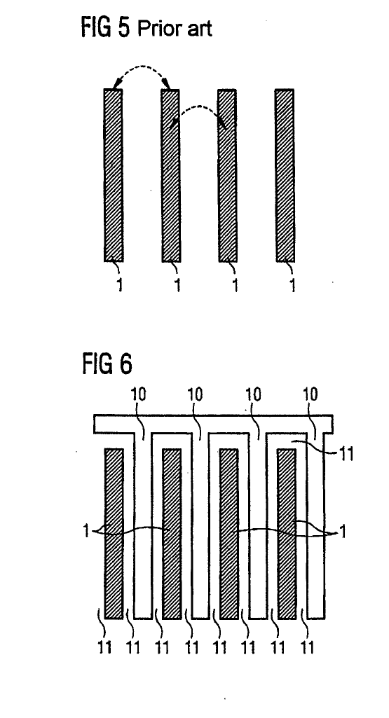

FIG. 5 shows the plan view of a schematic representation of a detail of the redistribution routing 1 in one layer level according to the prior art. The adjacent conductors, made to extend in parallel over wide ranges, of the redistribution routing 1 tend to transfer electrical crosstalk to one another (capacitive, inductive).

FIG. 6 finally shows the plan view of a schematic representation of a detail in the layer level of the redistribution routing 1 with ground conductors 10 arranged between the conductors of the redistribution routing 1. A shielding in the form of a conductor 10 connected to ground is respectively arranged between two of the adjacent conductors of the redistribution routing 1 made to extend in parallel over wide ranges, likewise parallel to these conductors, in the same layer level.

Between each conductor of the redistribution routing 1 and the adjacent conductor 10, a dielectric 11 is arranged in such a way that the conductor of the redistribution routing 1 and the adjacent ground conductors 10 lie next to one another without contact. As a result, electrical crosstalk between the adjacent conductors of the redistribution routing 1 is avoided, or reduced to the extent that signal falsifications can no longer occur.

1. A semiconductor chip comprising:
a substrate including active circuitry and metallization disposed over the active circuitry, the metallization coupling components of the active circuitry, the metallization including an upper metallization that leads to contacts for external connection of the substrate;
a first passivation layer overlying the substrate including over the upper metallization, the first passivation layer having a first dielectric constant;
a second passivation layer overlying the first passivation layer, the second passivation layer having a second dielectric constant that is less than the first dielectric constant, the second dielectric comprising a cold dielectric; and
a redistribution layer overlying the second passivation layer, the redistribution layer comprising patterned conductors that electrically couple the contacts to redistributed contacts.

2. The semiconductor chip as claimed in claim 1, wherein the second passivation layer extends over the entire surface of the first passivation layer.

3. The semiconductor chip as claimed in claim 1, wherein the second passivation is patterned in a pattern of the conductors of the redistribution layer.

4. The semiconductor chip as claimed in claim 3, wherein the second passivation layer protrudes laterally under the redistribution layer.

5. The semiconductor chip as claimed in claim 1, wherein the second passivation layer comprises a dielectric photo-patternable material.

6. The semiconductor chip as claimed in claim 4, wherein the photo-patternable material comprises a photoresist.

7. The semiconductor chip as claimed in claim 1, further comprising an additional conductor arranged between the conductors of the redistribution layer.

8. The semiconductor chip as claimed in claim 7, wherein the additional conductor is electrically coupled to a ground potential.

9. The semiconductor chip as claimed in claim 1, wherein conductors of the redistribution layer are separated from one another by air gaps.

10. The semiconductor chip as claimed in claim 1, wherein the redistribution layer comprises a Cu layer, an Ni layer overlying the Cu layer, and an Au layer overlying the Ni layer.

11. A semiconductor chip comprising:
a substrate including active circuitry and metallization disposed over the active circuitry, the metallization coupling components of the active circuitry, the metallization including an upper metallization that leads to contacts for external connection of the substrate;
a first passivation layer overlying the substrate including over the upper metallization, the first passivation layer having a first dielectric constant;
a redistribution layer overlying the second passivation layer, the redistribution layer electrically coupling the contacts to distributed contacts; and
a shielding conductor arranged between adjacent conductors of the redistribution layer.

12. The semiconductor chip as claimed in claim I 1, wherein the additional conductor is electrically coupled to a ground potential.

13. The semiconductor chip as claimed in claim 11, wherein the additional conductor extends substantially parallel to one of the adjacent conductors of the redistribution layer.

14. The semiconductor chip as claimed in claim 11, wherein the additional conductor lies in the same layer level of the redistribution layer.

15. The semiconductor chip as claimed in claim 11, further comprising a dielectric arranged between the conductor of the redistribution layer and the additional conductor.

16. The semiconductor chip as claimed in claim 11, further comprising an air gap between the conductor of the redistribution layer and the additional conductor.

17. The semiconductor chip as claimed in claim 11, wherein each conductor of the redistribution layer is arranged between two additional conductors.

18. The semiconductor chip as claimed in claim 11, further comprising a second passivation layer overlying the first passivation layer and underlying the redistribution layer, the second passivation layer having a second dielectric constant that is less than the first dielectric constant.

19. The semiconductor chip as claimed in claim 18, wherein the second passivation layer comprises a polyimide layer.

20. The semiconductor chip as claimed in claim 18, wherein the second passivation layer comprises a photosensitive material.
